(19) United States
(12) Patent Application Publication
(10) Pub. No.: US 2008/0150414 A1
(43) Pub. Date: Jun. 26, 2008

(54) Shadow mask apparatus and manufacturing method of organic electroluminescent display using the same

(75) Inventors: Un Cheol Sung, Anyang-Si (KR); Chang Mo Park, Seoul (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/897,917

(22) Filed: Aug. 30, 2007

(30) Foreign Application Priority Data
Dec. 26, 2006 (KR) 10-2006-0133695

(51) Int. Cl. H01J 1/62; H01J 9/00

(52) U.S. Cl. 313/498; 445/24

(57) ABSTRACT

The present invention relates to a shadow mask apparatus and a manufacturing method of an organic electroluminescent display using the same. According to the present invention, there is provided a shadow mask apparatus, including: a shadow mask frame including a first base plate, one or more first position alignment portions formed on a first surface of the first base plate, and one or more first hole patterns formed in the first position alignment portions; and a substrate holder disposed on the shadow mask frame to support the substrate, the substrate holder including a second base plate, one or more second position alignment portions formed on a third surface of the second base plate facing the first surface of the first base plate and formed to be coupled with the first position alignment portions, and one or more second hole patterns formed in the second position alignment portions, and a manufacturing method of an organic electroluminescent display using such a shadow mask apparatus.

### CROSS-REFERENCE TO RELATED APPLICATION

This application claims the benefit of priority of Korean Patent Application No. 10-2006-0133695 filed on Dec. 26, 2006, the disclosure of which is incorporated herein by reference in its entirety.

### BACKGROUND OF THE INVENTION

1. Technical Field

The present invention relates to a shadow mask apparatus and a manufacturing method of an organic electroluminescent display using the same, and more particularly, to a shadow mask apparatus and a manufacturing method of an organic electroluminescent display using the same, wherein position alignment between a substrate and a shadow mask is easily performed.

2. Discussion of the Related Art

An organic electroluminescent display which has been expected as a next generation flat panel display following liquid crystal displays (LCDs) and plasma display panels (PDPs) is a display using a phenomenon in which a current flows to emit light when multiple layers of organic compounds served as illuminants are laminated and voltage is applied thereto.

In the organic electroluminescent display, if a layer of an organic light emitting material is inserted between two electrodes and a voltage is applied across the two electrodes, electrons and holes are injected from the negative electrode and the positive electrode, respectively, into the organic layer so that the electrons and the holes are recombined with each other. The resulting recombination energy causes organic molecules in the organic layer to be excited, thereby generating light. Since this organic electroluminescent display has advantages of wide viewing angle, high definition, high quality and high response together with self-light-emitting characteristic, it has recently come into wider use.

The organic electroluminescent displays are classified into a small molecule type and a high polymer type according to property of an organic light emitting material. In the small molecule type, the organic light emitting material is deposited on a substrate by a thermal evaporation process or by a vapor phase deposition process. Currently, a shadow mask is used to deposit the organic light emitting material in a desired shape.

However it is difficult to align such a shadow mask on the substrate exactly within the tolerance required.

Furthermore, even if the position alignment is performed correctly, that is to say that the alignment is within the required tolerance, the substrate may sag in a case where the area of the substrate is large.

There is a first problem in that the organic light emitting material may be deposited with the correct pattern but with the location of the pattern misaligned. In addition there is a second problem in that the pattern may be distorted due to sagging of the substrate during the deposition process, and there is a third problem in that present alignment procedures are too difficult.

### SUMMARY OF THE INVENTION

The present invention provides a shadow mask that is easily and accurately aligned to a substrate. A further feature of the present invention provides a shadow mask that supports large area substrates with minimal sagging and thus minimizes distortion of the pattern in the deposited layer.

According to an exemplary embodiment of the present invention there is provided a shadow mask apparatus for supporting a substrate, the shadow mask apparatus comprising: a shadow mask frame including a first base plate, one or more first position alignment portions formed on a first surface of the first base plate, and one or more first hole patterns formed in the one or more first position alignment portions; and a substrate holder including a second base plate, one or more second position alignment portions formed on a third surface of the second base plate, the one or more second position alignment portions being adapted for mating with the one or more first position alignment portions, the substrate holder including one or more second hole patterns formed in the one or more second position alignment portions.

The substrate holder may further include one or more substrate fixing portions formed on a fourth surface of the second base plate opposite to the third surface of the second base plate, and wherein the substrate may be positioned between the one or more substrate fixing portions.

The one or more first position alignment portions may be formed to protrude from the first base plate to a predetermined height and the one or more second position alignment portions may be formed to be recessed into the second base plate to a predetermined depth.

The one or more first position alignment portions may be formed to be recessed into the first base plate to a predetermined depth and the one or more second position alignment portions may be formed to protrude from the second base plate to a predetermined height.

The one or more first position alignment portions may be formed in correspondence to a shape of the one or more first hole patterns and the one or more second position alignment portions may be formed in correspondence to a shape of the one or more second hole patterns.

The shadow mask frame and the substrate holder may be made of a metal material.

A plurality of the first position alignment portions may be formed to be positioned apart from each other by a predetermined interval, and at least one of the one or more first hole patterns may be formed in each of the plurality first position alignment portions.

A plurality of the second position alignment portions may be formed to be positioned apart from each other by a predetermined interval, and at least one of the one or more second hole patterns may be formed in each of the plurality of second position alignment portions.

The single first position alignment portion may be formed in which at least one of the one or more first hole patterns is formed.

The single second position alignment portion may be formed in which at least one of the one or more second hole patterns is formed.

The first base plate and the one or more first position alignment portions may be integrally formed.

The second base plate and the one or more second position alignment portions may be integrally formed.

The second base plate includes corner zones and the one or more substrate fixing portions may be formed at the corner zones with one of the one or more substrate fixing portions formed at each of the corner zones.

Each of the one or more first position alignment portions and each of the one or more second position alignment portions may be formed in the shape of a rectangular frame, each of the rectangular frames having a sidewall, wherein each sidewall may be formed to be inclined by a predetermined angle with respect to each base plate.

The predetermined height and the predetermined depth may be approximately equal to each other.

The predetermined angle may range from 30 to 60 degrees.

According to an exemplary embodiment of the present invention, there is provided a manufacturing method for manufacturing an organic electroluminescent display, comprising: providing a shadow mask apparatus for supporting a substrate, the shadow mask apparatus including; a shadow mask frame including, a first base plate, one or more first position alignment portions formed on a first surface of the first base plate, and one or more first hole patterns formed in the one or more first position alignment portions, and a substrate holder including a second base plate, one or more second position alignment portions formed on a third surface of the second base plate, the one or more second position alignment portions being adapted for mating with the one or more first position alignment portions, the substrate holder including one or more second hole patterns formed in the one or more second position alignment portions; placing a substrate on the substrate holder; mating the shadow mask frame with the substrate holder; and performing a deposition process.

The organic electroluminescent display may emit mono color.

The mono color may be white.

### BRIEF DESCRIPTION OF THE DRAWINGS

Exemplary embodiments of the present invention can be understood in more detail from the following descriptions taken in conjunction with the accompanying drawings, in which:

FIG. 1 is an exploded perspective view showing a shadow mask apparatus according to a first embodiment of the present invention;

FIG. 2 is a side view taken along line II-II in FIG. 1 showing the shadow mask apparatus;

FIG. 3A is a front perspective view schematically showing a shadow mask frame shown in FIG. 1;

FIG. 3B is a sectional view of the shadow mask frame taken along line IIIB-IIIB in FIG. 3A;

FIG. 3C is a rear perspective view showing the shadow mask frame 100 of FIG. 1.

FIG. 4A is a front perspective view showing the substrate holder 200 of FIG. 1;

FIG. 4B is a sectional view of the substrate holder taken along line IVB-IVB in FIG. 4A;

FIG. 4C is a rear perspective view showing the substrate holder of FIG. 1;

FIG. 5A is a plan view showing a state in which a substrate is positioned on a shadow mask apparatus;

FIG. 5B is a sectional view taken along line VB-VB in FIG. 5A;

FIG. 6 is a side view showing a shadow mask apparatus according to a second embodiment of the present invention;

FIG. 7 is an exploded perspective view showing a shadow mask apparatus according to a third embodiment of the present invention;

FIGS. 8A to 8F are sectional views showing an example of a manufacturing method of an organic electroluminescent display using the shadow mask apparatus according to the present invention.

### DETAILED DESCRIPTION OF THE PREFERRED EMBODIMENT

Exemplary embodiments of the invention are described more fully hereinafter with reference to the accompanying drawings. This invention may, however, be embodied in many different forms and should not be construed as limited to the embodiments set forth herein.

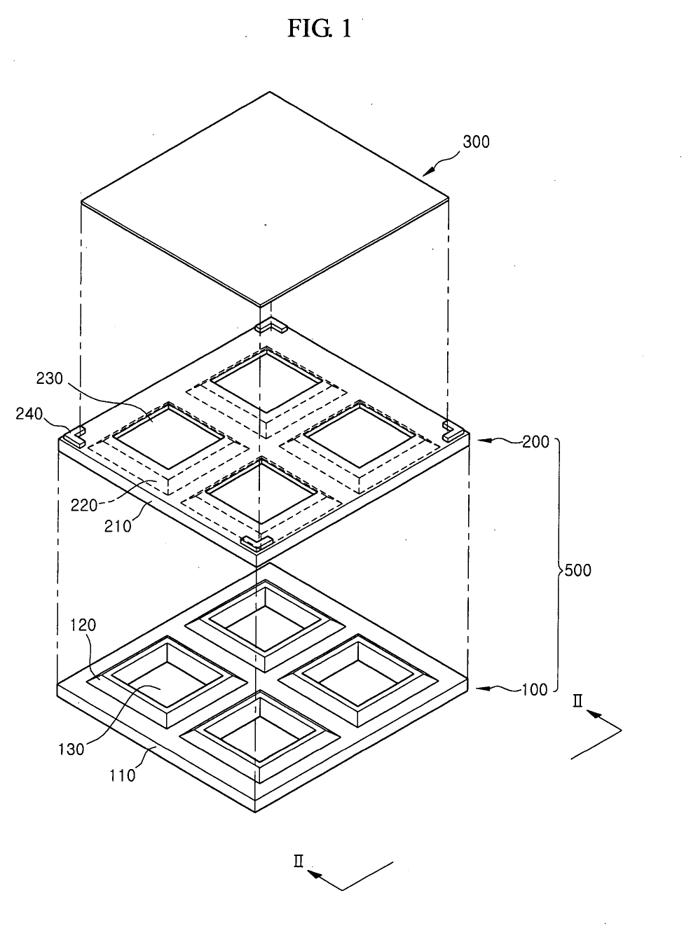

FIG. 1 is an exploded perspective view showing a shadow mask apparatus according to a first embodiment of the present invention, and FIG. 2 is a side view showing the shadow mask apparatus shown in FIG. 1.

Referring to FIGS. 1 and 2, a shadow mask apparatus 500 according to the first embodiment of the present invention includes a shadow mask frame 100 and a substrate holder 200.

The shadow mask frame 100 is a component, which is coupled with the substrate holder 200 to support the substrate holder 200, the combination serving as a shadow mask. The substrate holder 200 is a component, which is disposed on the shadow mask frame 100 to support the substrate 300.

The shadow mask frame 100 includes a first base plate 110, first position alignment portions 120 and first hole patterns 130. The substrate holder 200 includes a second base plate 210, second position alignment portions 220, second hole patterns 230 and substrate fixing portions 240. The first position alignment portions 120 are formed on an upper surface of the first base plate 110 of the shadow mask frame 100. Each of the first position alignment portions 120 is configured to protrude from the first base plate 110 by a predetermined height. Each of the first hole pattern 130 is formed in the first position alignment portion 120 and bored through the first position alignment portion 120 and the first base plate 110.

The second position alignment portions 220 are formed on a lower surface of the second base plate 210 of the substrate holder 200, i.e., on a surface facing the upper surface of the first base plate 110. Each of the second position alignment portions 220 is configured to be recessed in correspondence to the first position alignment portion 120 in shape and height, thereby being reciprocally coupled with the first position alignment portion 120 formed on the first base plate 110. Each of the second hole patterns 230 is formed in the second position alignment portion 220. At this time, the second hole pattern 230 may be configured in correspondence to the first hole pattern 130 in size and shape.

The substrate fixing portions 240 for guiding a position of the substrate 300 are formed on an upper surface of the second base plate 210, i.e., on a surface opposite to the surface on which the second position alignment portions 220 are formed. The substrate fixing portions 240 are respectively formed on corner zones, i.e., four corner zones, of the second base plate 210 with a predetermined height, thereby providing a position, between the substrate fixing portions, in which the substrate 300 is placed on the substrate holder 200. In the present embodiment of the invention, each of the substrate fixing portions 240 are configured in the form of an L-shaped protrusion on each of four corner zones of the second base plate 210, but the present invention is not limited to this configuration. The shape, number and position of the- substrate fixing portions 240 may be changed in various ways.

The shadow mask apparatus according to the embodiment of the present invention will be described in more detail with reference to the drawings.

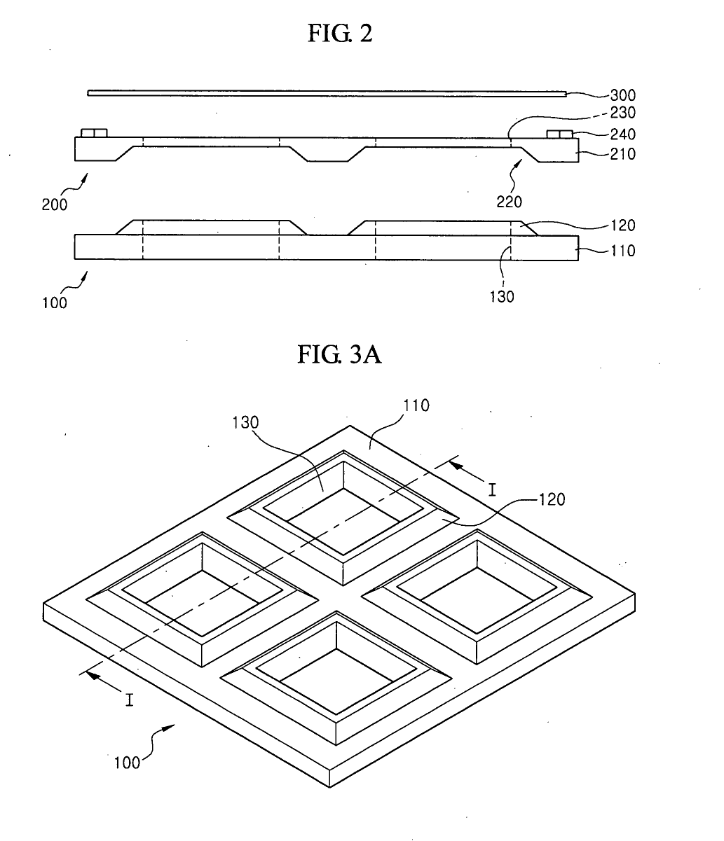

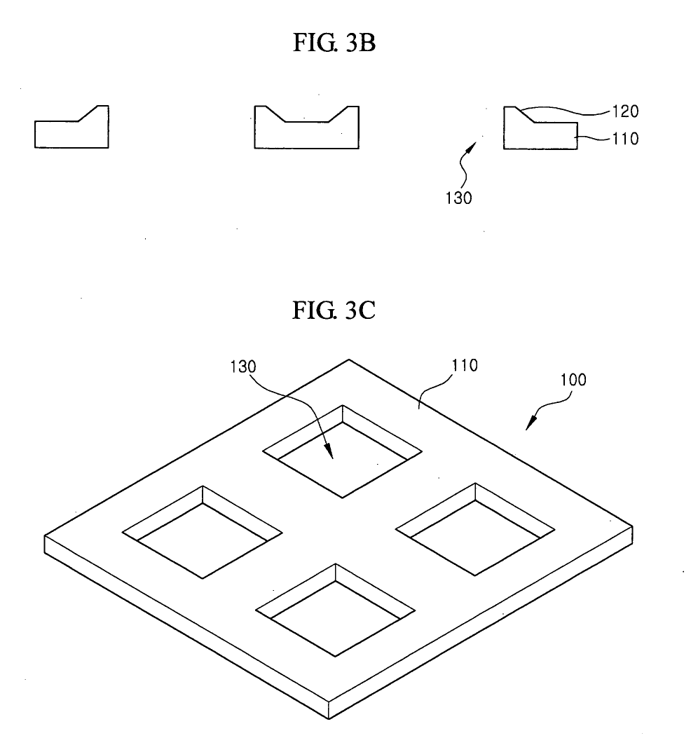

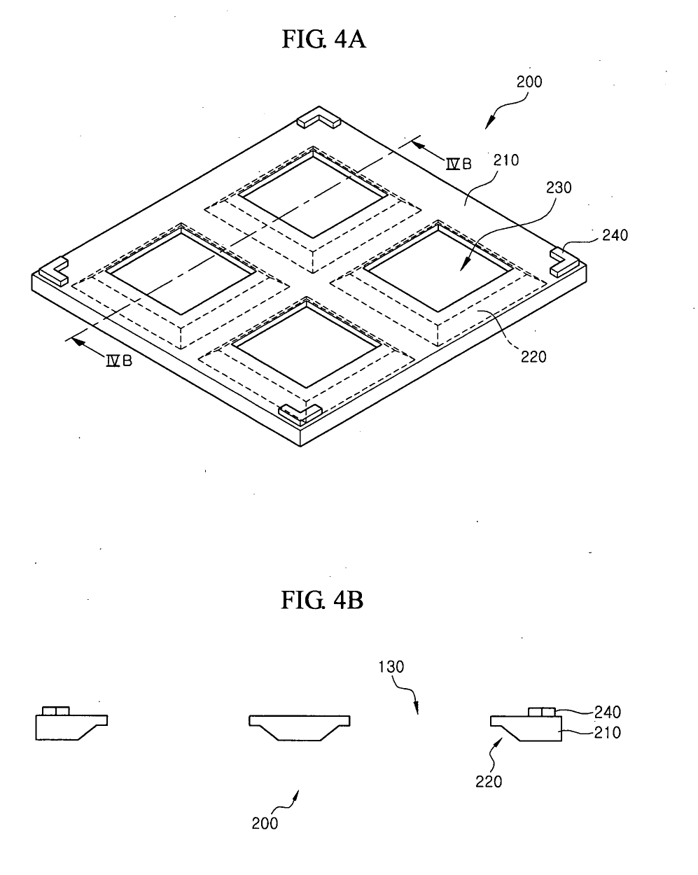

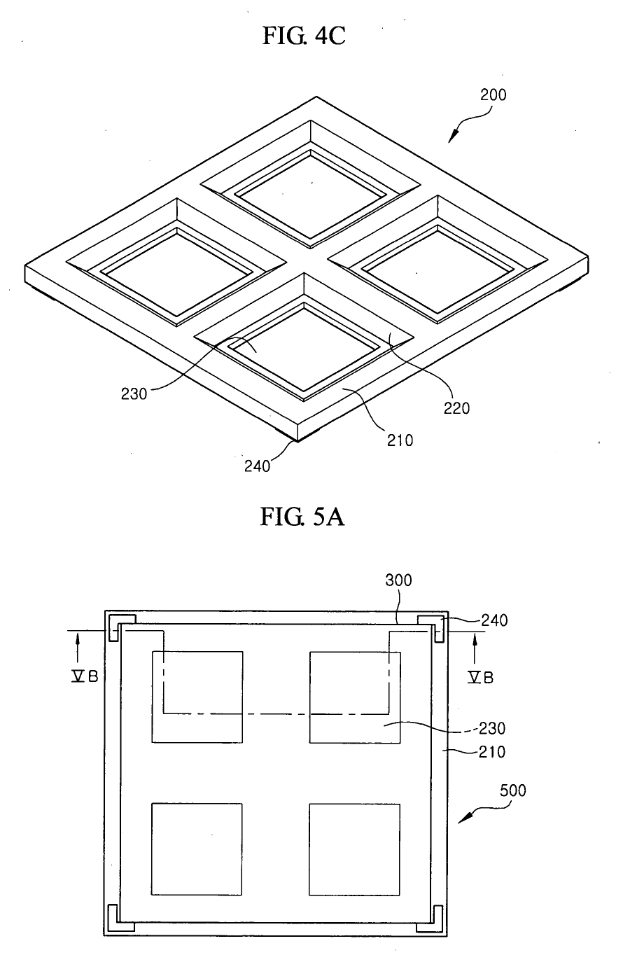

FIG. 3A is a front perspective view showing a shadow mask frame shown in FIG. 1, FIG. 3B is a sectional view of the shadow mask frame taken along line IIIB-IIIB in FIG. 3A, and FIG. 3C is a rear perspective view showing the shadow mask frame shown in FIG. 1. FIG. 4A is a front perspective view schematically showing a substrate holder shown in FIG. 1, FIG. 4B is a sectional view of the substrate holder taken along line IVB-IVB in FIG. 4A, and FIG. 4C is a rear perspective view showing the substrate holder shown in FIG. 1. FIG. 5A is a plan view showing a state in which a substrate is positioned on a shadow mask apparatus 500, and FIG. 5B is a sectional view taken along line VB-VB in FIG. 5A.

Referring to FIGS. 3A to 3C, the shadow mask frame 100 includes the first base plate 110, the first position alignment portion 120 and the first hole pattern 130.

All the four first position alignment portions 120, each of which is formed in the shape of a rectangular frame, are formed on the upper surface of the first base plate 110. The first position alignment portions 120 are configured to be positioned apart from each other by a predetermined interval and to protrude by a predetermined height. The first position alignment portions 120 and the first base plate 110 may be integrally formed. Furthermore, each sidewall of the first position alignment portions 120 is configured to be inclined at a first angle with respect to the first base plate 110. The first angle may range from 30 to 60 degrees.

The first hole pattern 130 is formed to have a predetermined shape in order to expose a deposition zone of the substrate (not shown). That is, the first hole pattern 130 is formed in a shape corresponding to that of the first position alignment portion 120, i.e., in the shape of a rectangular frame. The first hole pattern 130 is formed to be bored through the first position alignment portion 120 and the first base plate 110. Furthermore, as shown in FIG. 3B, the first hole pattern 130 may be formed to have the same diameter at the first position alignment portion 120 and at the first base plate 110. Alternatively, the first hole pattern 130 may be formed-to have a diameter at the first base plate 110 larger than that at the first position alignment portion 120. That is, the first hole pattern 130 may be formed to have a the cross section of not a rectangular shape but a trapezoid shape whose lower side is longer.

The shadow mask frame 100 may be made of a metal material in the present embodiment. Furthermore, although it is described in the present embodiment that all the four first position alignment portions 120 and all the four first hole patterns 130 are formed and each of them is formed in the shape of a rectangular frame, the number and shape of the first position alignment portions 120 and of the first hole patterns 130 is not limited thereto but may be changed in various ways.

Referring to FIGS. 4A to 4C, the substrate holder 200 includes the second base plate 210, the second position alignment portions 220, the second hole patterns 230 and the substrate fixing portions 240.

All the four second position alignment portions 220, each of which is in the shape of a rectangular frame, are formed on the lower surface of the second base plate 210. The second position alignment portions 220, each of which is formed to be recessed by a predetermined depth, are formed to be positioned apart from each other by a predetermined interval. The second position alignment portion 220 is formed to be recessed by a depth corresponding to the protruding height of the first position alignment portion 120, and the shape of the second position alignment portion 220 also corresponds to that of the first position alignment portion 120. Furthermore, each sidewall of the second position alignment portion 220 is formed to be inclined at a second angle with respect to the second base plate 210. The second angle is formed to be identical to the first angle, i.e., in the range from 30 to 60 degrees.

The second hole pattern 230 is formed to have a predetermined shape in order to expose the deposition zone of the substrate (not shown). That is, the second hole pattern 230 is formed corresponding to the shape of the first hole pattern 130, i.e., in the shape of a rectangular frame in the second position alignment portion 220.

The substrate holder 200 may be made of a metal material in the present embodiment. Furthermore, although it is exemplarily described in the present embodiment that all the four second position alignment portions 220 and all the four second hole patterns 230, each of which is in the shape of a rectangular frame, are formed, the number and shape of the second position alignment portions 220 and the second hole patterns 230 is not limited thereto but may be changed in various ways.

Referring to FIGS. 5A and 5B, the substrate holder 200 is disposed on the shadow mask frame 100 to be reciprocally coupled thereto, and the substrate 300 is rested on the substrate holder 200.

The first position alignment portions 120 of the shadow mask frame 100 are formed to protrude, and the second position alignment portions 220 of the substrate holder 200 are formed to be recessed. Therefore, when the substrate holder 200 is disposed on the shadow mask frame 100, the upper surface of the first base plate 110 and the lower surface of the second base plate 210 are brought into contact with each other, so that they are disposed to be engaged and aligned with each other. Since the first hole patterns 130 of the shadow mask frame 100 and the second hole patterns 230 of the substrate holder 200 are also aligned to each other, the position alignment between the substrate and the shadow mask apparatus can be extremely facilitated.

Furthermore, since the substrate holder 200 is shaped to have a lattice structure it causes a middle zone of the substrate to be supported even if the substrate 300 has a large area, and it prevents sagging of the substrate.

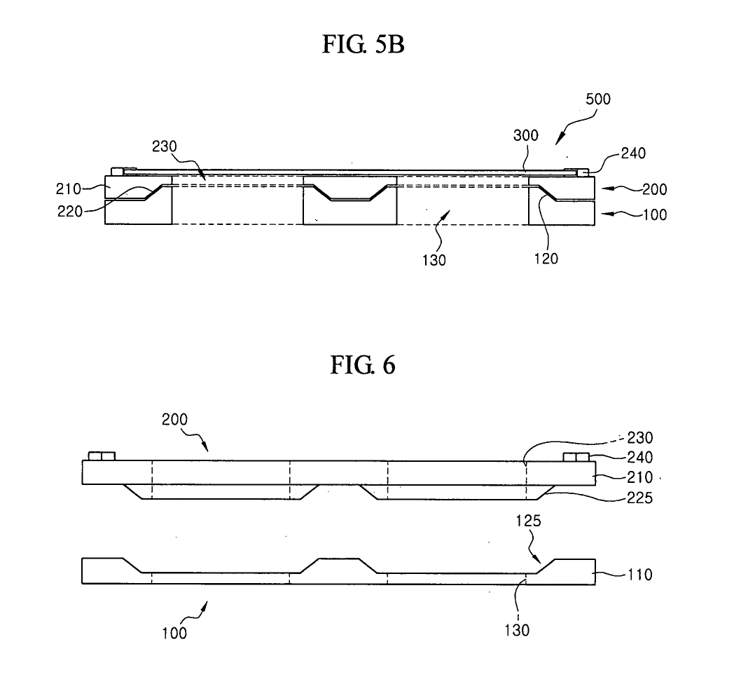

FIG. 6 is a side view showing a shadow mask apparatus according to a second embodiment of the present invention. The second embodiment shown in FIG. 6 has a structure of first and second position alignment portions different from those of the first embodiment as described above. The other components of both the embodiments are substantially identical to each other, so that such different components will be primarily described in detail below.

Referring to FIG. 6, the shadow mask apparatus includes a shadow mask frame 100 and a substrate holder 200. The shadow mask frame 100 includes a first base plate 110, first position alignment portions 125 and first hole patterns 130. The substrate holder 200 includes a second base plate 210, second position alignment portions 225, second hole patterns 230 and substrate fixing portions 240.

The first position alignment portions 125 are formed on the upper surface of the first base plate 110 of the shadow mask frame 100. The first position alignment portions 125 are formed to be recessed from the first base plate 110 by a predetermined depth, and the first hole patterns 130 are respectively formed in the first position alignment portions 125.

The second position alignment portions 225 are formed on the lower surface of the second base plate 210 of the substrate holder 200, i.e., on the surface facing the upper surface of the first base plate 110. The second position alignment portions 225 are formed to protrude in correspondence to the shape and depth of the first position alignment portions 125, thereby being coupled with the first position alignment portions 125 formed on the first base plate 110. The second hole patterns 230 are respectively formed in the second position alignment portions 225. At this time, the second hole patterns 230 are formed in correspondence to the size and shape of the first hole pattern 130, and the second hole patterns 230 are formed to extend through the second position alignment portions 225 and the second base plate 210.

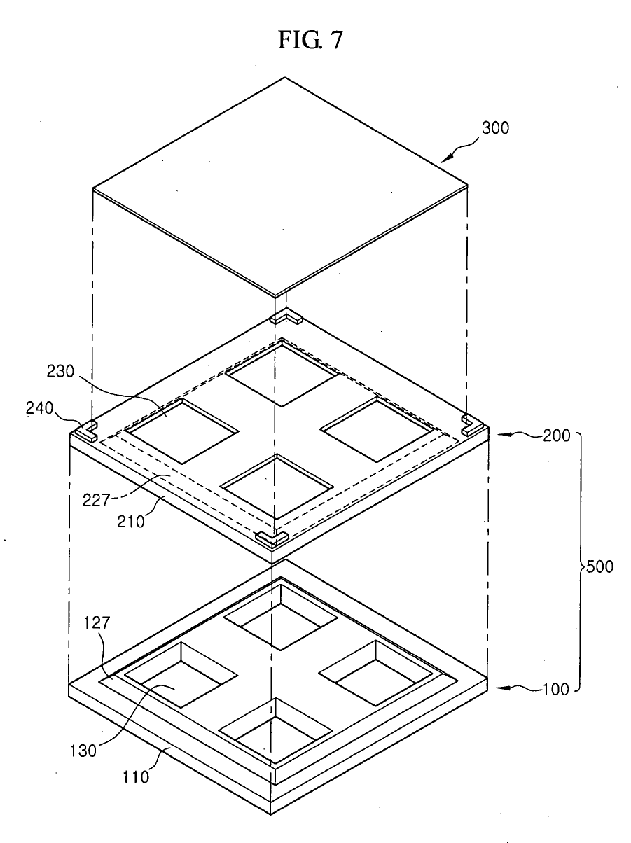

FIG. 7 is an exploded perspective view showing a shadow mask apparatus according to a third embodiment of the present invention. The third embodiment shown in FIG. 7 has a structure of first and second position alignment portions different from those of the first embodiment as described above. The other components of both the embodiments are substantially identical to each other, so that such different components will be primarily described in detail below.

Referring to FIG. 7, the shadow mask apparatus includes a shadow mask frame 100 and a substrate holder 200. The shadow mask frame 100 includes a first base plate 110, a first position alignment portion 127 and first hole patterns 130. The substrate holder 200 includes a second base plate 210, a second position alignment portion 227, second hole patterns 230 and substrate fixing portions 240.

Referring to the shadow mask frame 100 according to the present embodiment, the single first position alignment portion 127 is formed to protrude on the upper surface of the first base plate 110 by a predetermined height on the first base plate 110. A plurality of the first hole patterns 130 (i.e., the four first hole patterns 130 in case of the present embodiment) are formed in the first position alignment portion 127 to be positioned apart from each other by a predetermined interval.

Referring to the substrate holder 200, the single second position alignment portion 227 is formed to be recessed in the upper surface of the second base plate 210 by a predetermined depth in the second base plate 210. A plurality of the second hole patterns 230 (i.e., the four second hole patterns 230 in case of the present embodiment) are formed in the single second position alignment portion 227 to be positioned apart from each other by a predetermined interval. The single second position alignment portion 227 is formed in correspondence to the configuration of the single first position alignment portion 127. The present embodiment is not limited to a single first position alignment portion and a single second position alignment portion but may include a plurality of each.

Furthermore, it is described in the present embodiment that only the single first position alignment portion is formed, but two first position alignment portions may be formed and then a plurality of (i.e., two or more) first hole patterns may be formed in each of the two first position alignment portions. Similarly, the second position alignment portions may be configured as described above.

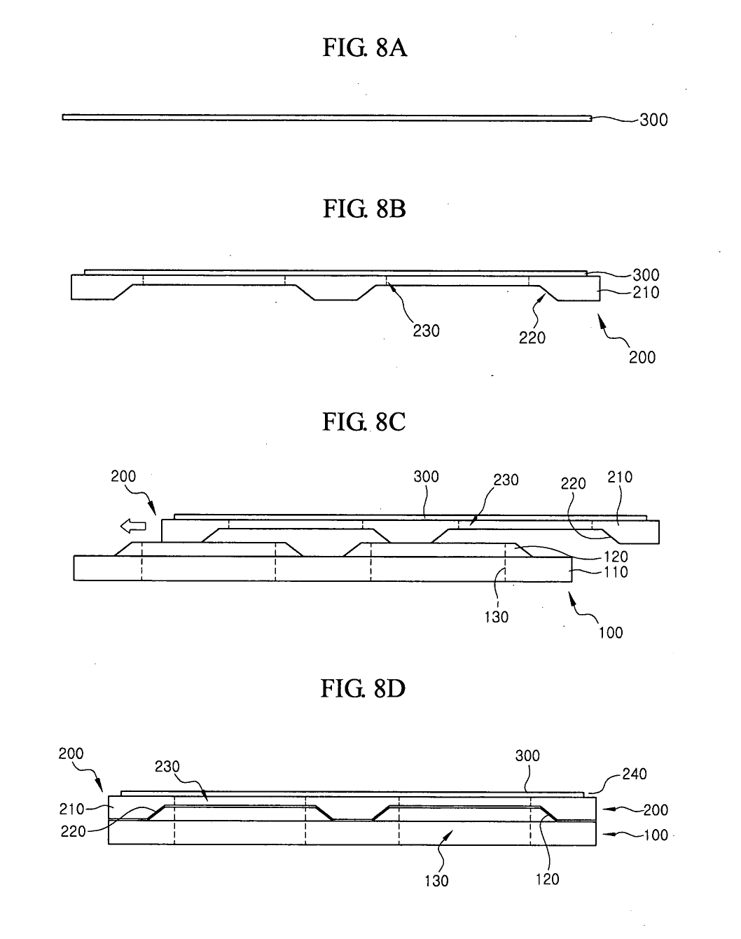

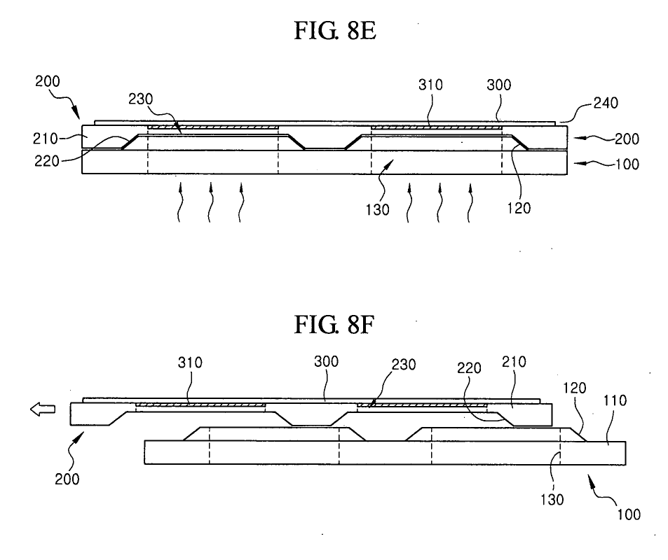

FIGS. 8A to 8F are sectional views schematically showing an example of a manufacturing method of an organic electroluminescent display using the shadow mask apparatus according to the present invention. Since the shadow mask apparatus used in the present embodiment corresponds to the shadow mask apparatus of the first embodiment described in detail above, the redundant descriptions related to the shadow mask apparatus will be omitted.

Referring to FIGS. 8A and 8B, the substrate 300 is prepared, and then the prepared substrate 300 is rested on the substrate holder 200. At this time, the substrate 300 may be a transparent insulative substrate, e.g., a glass or plastic substrate. As described above, the substrate holder 200 includes the second base plate 210, the second position alignment portions 220 formed in the lower surface of the second base plate 210, the second hole patterns 230 formed in the second position alignment portions 220, and the substrate fixing portions (not shown) formed on the upper surface of the second base plate 210.

The substrate 300 is rested on the upper surface of the second base plate 210 of the substrate holder 200 with the rested position of the substrate 300 guided by the substrate fixing portions.

Referring to FIGS. 8C and 8D, the substrate holder 200 on which the substrate 300 is rested is disposed on the shadow mask frame 100 and then is allowed to slide along a direction, whereby the substrate holder 200 and the shadow mask frame 100 may be coupled with each other.

As described above, the shadow mask frame 100 includes the first base plate 110, the first position alignment portions 120 formed on the upper surface of the first base plate 110, and the first hole patterns 130 formed in the first position alignment portions 120.

The first position alignment portions 120 of the shadow mask frame 100 and the second position alignment portions 220 of the substrate holder 200 are formed so that they are easily coupled with each other. Therefore, if the substrate holder 200 is disposed on the shadow mask frame 100 and then moved, the substrate holder 200 is allowed to slide, so that the substrate holder 200 and the shadow mask frame 100 are coupled with each other. As a result, the first hole patterns 130 and the second hole patterns 230 are also aligned with each other by themselves.

Referring to FIGS. 8E and 8F, if the substrate holder 200 on which the substrate 300 is rested is coupled with the shadow mask frame 100, a process of depositing a predetermined material, e.g., an organic light emitting material on the substrate 300, is performed (FIG. 8E).

If the deposition process is performed, a deposition layer 310 with a predetermined shape, i.e., a shape defined by the first hole patterns 130 and the second hole patterns 230, is formed on the substrate 300. Then, the substrate holder 200 on which the substrate 300 with deposition layer 310 formed thereon is rested is separated from the shadow mask frame 100, so that next processes may be performed.

The manufacturing method according to the present embodiment may be applied to an organic electroluminescent display for emitting mono color light or white color light, but the present invention is not limited thereto.

According to the present invention as described above, the position alignment between the substrate and the shadow mask can be easily performed.

Furthermore, even if a substrate has a large area, the substrate can be prevented from sagging since the substrate is supported by the substrate holder.

The above descriptions are merely exemplary embodiments of a shadow mask apparatus according to the present invention and a manufacturing method of the organic electroluminescent display using the same. Thus, the present invention is not limited to the above embodiments. The true scope of the present invention should be defined to the extent that those skilled in the art can make various modifications and changes thereto without departing from the scope of the invention, as defined by the appended claims.

What is claimed is:

1. A shadow mask apparatus comprising:
a shadow mask frame including a first base plate, one or more first position alignment portions formed on a first surface of the first base plate, and one or more first hole patterns formed in the one or more first position alignment portions; and
a substrate holder including a second base plate, one or more second position alignment portions formed on a third surface of the second base plate, the one or more second position alignment portions being adapted for mating with the one or more first position alignment portions, the substrate holder including one or more second hole patterns formed in the one or more second position alignment portions.

2. The shadow mask apparatus as claimed in claim 1, wherein the substrate holder further includes one or more substrate fixing portions formed on a fourth surface of the second base plate opposite to the third surface of the second base plate, and wherein the substrate may be positioned between the one or more substrate fixing portions.

3. The shadow mask apparatus as claimed in claim 1, wherein the one or more first position alignment portions are formed to protrude from the first base plate to a first height and the one or more second position alignment portions are formed to be recessed into the second base plate to a first depth.

4. The shadow mask apparatus as claimed in claim 1, wherein the one or more first position alignment portions are formed to be recessed into the first base plate to a first depth and the one or more second position alignment portions are formed to protrude from the second base plate to a first height.

5. The shadow mask apparatus as claimed in claim 1, wherein the one or more first position alignment portions are formed in correspondence to a shape of the one or more first hole patterns and the one or more second position alignment portions are formed in correspondence to a shape of the one or more second hole patterns.

6. The shadow mask apparatus as claimed in claim 1, wherein the shadow mask frame and the substrate holder are made of a metal material.

7. The shadow mask apparatus as claimed in claim 1, wherein a plurality of the first position alignment portions are formed to be positioned apart from each other by a predetermined interval, and at least one of the one or more first hole patterns is formed in each of the plurality of first position alignment portions.

8. The shadow mask apparatus as claimed in claim 1, wherein a plurality of the second position alignment portions are formed to be positioned apart from each other by a predetermined interval, and at least one of the one or more second hole patterns is formed in each of the plurality of second position alignment portions.

9. The shadow mask apparatus as claimed in claim 1, wherein the single first position alignment portion is formed in which at least one of the one or more first hole patterns is formed.

10. The shadow mask apparatus as claimed in claim 1, wherein the single second position alignment portion is formed in which at least one of the one or more second hole patterns is formed.

11. The shadow mask apparatus as claimed in claim 1, wherein the first base plate and the one or more first position alignment portions are integrally formed.

12. The shadow mask apparatus as claimed in claim 1, wherein the second base plate and the one or more second position alignment portions are integrally formed.

13. The shadow mask apparatus as claimed in claim 2, wherein the second base plate includes corner zones and the one or more substrate fixing portions are formed at the corner zones, wherein one of the one or more substrate fixing portions is formed at each of the corner zones, respectively.

14. The shadow mask apparatus as claimed in claim 3 or 4, wherein each of the one or more first position alignment portions and each of the one or more second position alignment portions is formed in the shape of a rectangular frame, each rectangular frame having a sidewall, wherein each sidewall is formed to be inclined by a predetermined angle with respect to each base plate.

15. The shadow mask apparatus as claimed in claim 3 or 4, wherein the first height and the first depth are approximately equal to each other.

16. The shadow mask apparatus as claimed in claim 14, wherein the angle ranges from 30 to 60 degrees.

17. A manufacturing method for manufacturing an organic electroluminescent display, comprising:
providing a shadow mask apparatus comprising:
a shadow mask frame including a first base plate, one or more first position alignment portions formed on a first surface of the first base plate, and one or more first hole patterns formed in the one or more first position alignment portions; and
a substrate holder, the substrate holder including a second base plate, one or more second position alignment portions formed on a third surface of the second base plate, the one or more second position alignment portions being adapted for mating with the one or more first position alignment portions, the substrate holder including one or more second hole patterns formed in the one or more second position alignment portions;
placing a substrate on the substrate holder;
mating the shadow mask frame with the substrate holder; and
performing a deposition process.

18. The manufacturing method as claimed in claim 17, wherein the organic electroluminescent display emits mono color.

19. The manufacturing method as claimed in claim 18, wherein the mono color is white.
